(19) United States
(12) Patent Application Publication
(10) Pub. No.: US 2014/0183607 A1
(43) Pub. Date: Jul. 3, 2014

(54) Complementary Metal-Oxide-Semiconductor (CMOS) X-Ray Detector With A Repaired CMOS Pixel Array

(71) Applicant: GENERAL ELECTRIC COMPANY, Schenectady, NY (US)

(72) Inventor: James Liu, Salt Lake City, UT (US)

(73) Assignee: GENERAL ELECTRIC COMPANY, Schenectady, NY (US)

(21) Appl. No.: 13/728,713

(22) Filed: Dec. 27, 2012

(51) Int. Cl. H01L 31/115; H01L 31/18

(52) U.S. Cl. CPC H01L 31/115; H01L 31/18
USPC 257/292; 438/4

(57) ABSTRACT

A digital X-ray detector includes a scintillator that is configured to absorb radiation emitted from an X-ray radiation source and to emit light photons in response to the absorbed radiation. The detector also includes a complementary metal-oxide-semiconductor (CMOS) light imager that is configured to absorb the light photons emitted by the scintillator. The CMOS light imager includes a first surface and a second surface. The first surface is disposed opposite the second surface. The scintillator contacts the first surface of the CMOS light imager. The CMOS light imager further includes a repaired CMOS pixel array with at least one defective CMOS pixel isolated from a common column data line, a row select scan line, or a rest line within the CMOS pixel array.

### BACKGROUND OF THE INVENTION

The subject matter disclosed herein relates generally to an X-ray detector, and more particularly to a digital complementary metal-oxide-semiconductor (CMOS) X-ray detector with a repaired CMOS pixel array by isolating defective CMOS pixels for increasing the manufacturing yield of a CMOS X-ray detector.

The use of digital X-ray imaging systems continues to become increasingly invaluable with respect to a variety of technical applications. Digital X-ray imaging systems are a mainstay in the medical field allowing health care professionals to quickly diagnose and treat internal abnormalities of their patients. Additionally, their use has become increasingly important in industrial fields for visualizing internal contents of parts, baggage, parcels, and other objects, and for visualizing the contents and structural integrity of objects and for other purposes. Indeed, the evolution of digital X-ray detectors has enhanced both workflow and image quality of digital X-ray imaging systems.

Generally, X-ray imaging involves the generation of X-rays that are directed toward an object of interest. The X-rays pass through and around the object and then impact an X-ray film, X-ray cassette, or digital X-ray detector. In the context of the digital X-ray detector, X-ray photons traverse a scintillator that converts the X-ray photons to visible light, or light photons. The light photons then collide with a detector array that includes photosensing elements and electronic components that convert the light photons into electrical signals which are processed as digital image data and into digital images that can be viewed, stored, and/or transmitted electronically. As digital X-ray detectors continue to replace conventional X-ray film and X-ray cassettes, the need for improving the efficiency and image quality of digital X-ray imaging remains at the forefront.

The evolution of digital X-ray detectors has included the development of CMOS based digital X-ray detectors. Digital CMOS X-ray detectors are drawing more attention and becoming more popular in the area of fluoroscopic X-ray imaging especially in surgical and interventional applications because they exhibit extremely low electronic noise. However, one of the problems associated with digital CMOS X-ray detectors are their high cost compared to traditional amorphous silicon based digital X-ray detectors. The high cost of the digital CMOS X-ray detectors is due to a low manufacturing yield. A key failure mode that impacts the manufacturing yield of these detectors is defective lines in the CMOS detector arrays that create image artifacts in resulting images.

The subject matter of this disclosure greatly improves the manufacturing yield and reduces the cost of digital CMOS X-ray detectors by repairing CMOS pixel arrays by isolating defective CMOS pixels from the CMOS pixel array.

### BRIEF DESCRIPTION OF THE INVENTION

In accordance with one embodiment, a digital X-ray detector is provided. The detector includes a scintillator that is configured to absorb radiation emitted from an X-ray radiation source and to emit light photons in response to the absorbed radiation. The detector also includes a complementary metal-oxide-semiconductor (CMOS) light imager that is configured to absorb the light photons emitted by the scintillator. The CMOS light imager includes a first surface and a second surface. The first surface is disposed opposite the second surface, and the scintillator contacts the first surface of the CMOS light imager. The CMOS light imager further includes a repaired CMOS pixel array with at least one defective CMOS pixel isolated from a common column data line, a row select scan line, or a rest line within the CMOS pixel array.

In accordance with another embodiment, a detector array is provided. The detector array includes a scintillator that is configured to absorb radiation emitted from an X-ray radiation source and to emit light photons in response to the absorbed radiation. The detector also includes a complementary metal-oxide-semiconductor (CMOS) light imager that is configured to absorb the light photons emitted by the scintillator. The scintillator contacts the CMOS light imager. The CMOS light imager includes a repaired CMOS pixel array with at least one defective CMOS pixel isolated from a common column data line, a row select scan line, or a rest line within the CMOS pixel array.

In accordance with a further embodiment, a method is provided for repairing a CMOS pixel array. The method includes identifying defective CMOS pixels within the CMOS pixel array and isolating the defective CMOS pixels from the CMOS pixel array by cutting at least one trace between a defective CMOS pixel and a common column data line, a row select scan line, or a reset line.

The brief descriptions set forth above are exemplary and not intended to be limiting, and combinations or alternate embodiments thereof are considered to be within the scope of the present disclosure.

### BRIEF DESCRIPTION OF THE DRAWINGS

These and other features, aspects, and advantages of the disclosed subject matter will become better understood when the following detailed description is read with reference to the accompanying drawings in which like characters represent like parts throughout the drawings, wherein:

FIG. 1 is a block diagram of an exemplary embodiment of a digital X-ray imaging system;

FIG. 2 is a cross-sectional schematic view of an exemplary embodiment of a digital complementary metal-oxide-semiconductor (CMOS) X-ray detector;

FIG. 3 is a schematic diagram of an exemplary embodiment of a repaired CMOS pixel array within a digital CMOS X-ray detector with a defective CMOS pixel isolated from a common column data line;

FIG. 4 is a schematic diagram of an exemplary embodiment of a repaired CMOS pixel array within a digital CMOS X-ray detector with a defective CMOS pixel isolated from a row select scan line; and

FIG. 5 is a schematic diagram of an exemplary embodiment of a repaired CMOS pixel array within a digital CMOS X-ray detector with a defective CMOS pixel isolated from a reset line.

### DETAILED DESCRIPTION OF THE INVENTION

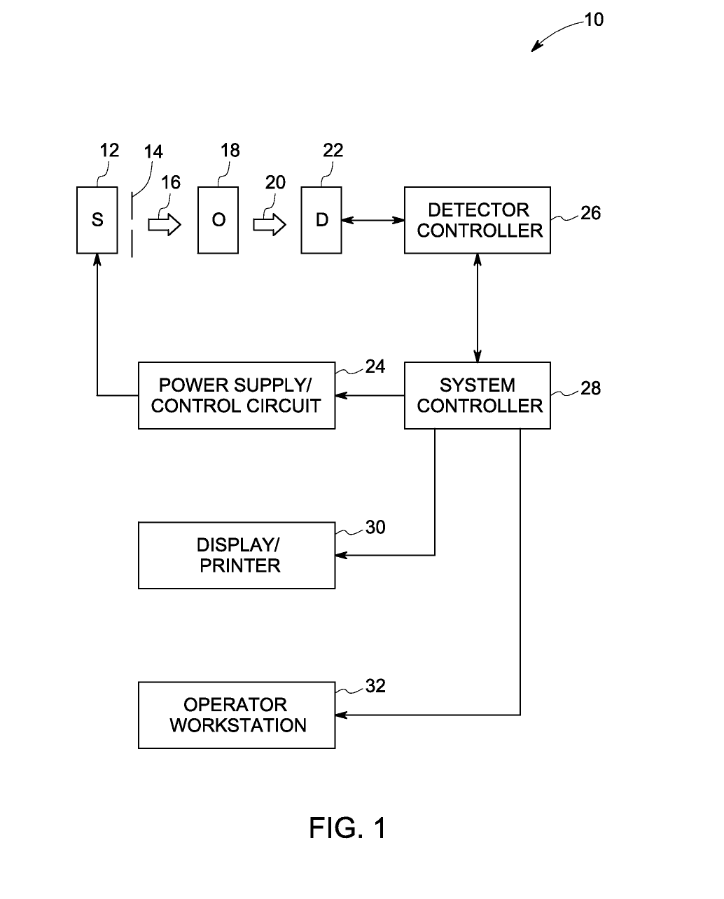

Referring to the drawings, FIG. 1 illustrates a block diagram of an exemplary embodiment of a digital X-ray imaging system 10 for acquiring original image data and processing the image data for display. The digital X-ray imaging system 10 includes an X-ray radiation source 12 positioned adjacent to a collimator 14. The collimator 14 permits a stream of X-ray radiation 16 to pass into a region in which an object or subject 18 is positioned.

A portion of the X-ray radiation 20 passes through or around the object or subject 18 and impacts a digital X-ray detector 22. In certain embodiments, the detector 22 may include a complementary metal-oxide-semiconductor (CMOS) based detector. As will be appreciated by those skilled in the art, the digital X-ray detector 22 may convert the X-ray radiation photons received on its surface to lower energy light photons, and subsequently to electric signals, which are acquired and processed to reconstruct an image of the features within the object or subject.

The X-ray radiation source 12 is controlled by a power supply/control circuit 24 which supplies both power and control signals for examination sequences. Moreover, the digital X-ray detector 22 is communicatively coupled to a detector controller 26 which commands acquisition of the signals generated in the detector 22. In certain embodiments, the detector 22 may communicate with the detector controller 26 via any suitable wireless communication standard, although the use of digital X-ray detectors 22 that communicate with the detector controller 26 through a cable, tether or some other mechanical connection are also envisaged. The detector controller 26 may also execute various signal processing and filtration functions, such as for initial adjustment of dynamic ranges, interleaving of digital image data, and so forth.

Both the power supply/control circuit 24 and the detector controller 26 are responsive to signals from a system controller 28. In general, the system controller 28 commands operation of the imaging system to execute examination protocols and to process acquired image data. In the present context, the system controller 28 also includes signal processing circuitry, typically based upon a programmed general purpose or application-specific digital computer, associated memory circuitry, such as optical memory devices, magnetic memory devices, or solid-state memory devices, for storing programs and routines executed by a processor of the computer to carry out various functionalities, as well as for storing configuration parameters and image data, interface circuits, and so forth.

In the embodiment illustrated in FIG. 1, the system controller 28 is linked to at least one output device, such as a display or printer 30. The output device may include standard or special purpose computer monitors and associated processing circuitry. One or more operator workstations 32 may be further linked in the system for selecting system parameters, requesting examinations, viewing images, and so forth. In general, displays, printers, workstations, and similar devices supplied within the system may be local to the data acquisition components, or may be remote from these components, such as elsewhere within an institution or medical facility, or in an entirely different location, linked to the image acquisition system via one or more configurable networks, such as the Internet, virtual private networks, and so forth.

The digital X-ray imaging system 10 as shown in FIG. 1 may also include a variety of alternative embodiments generally configured to meet the particular needs of certain applications. In certain embodiments, the digital X-ray imaging system 10 may be a fixed or mobile radiography system, a tomosynthesis system, a fluoroscopy system, a computed tomography (CT) system, or any combination thereof. As examples, the digital X-ray imaging system 10 may be a fixed radiography or tomosynthesis system where the digital X-ray detector 22 is either permanently mounted together with the system or portable for positioning in a table or wall stand, a mobile radiography system where the digital X-ray detector 22 is portable or tethered, a fixed fluoroscopy system where the digital X-ray detector 22 is permanently mounted within the system, or a mobile fluoroscopy system where the digital X-ray detector 22 is permanently positioned opposite of the X-ray radiation source 12.

Throughout the following discussion, while basic and background information is provided on the digital X-ray imaging system used in medical diagnostic applications, it should be born in mind that aspects of the present subject matter may be applied to digital X-ray detectors used in different settings (e.g., projection imaging, computed tomography imaging, and tomosynthesis imaging, etc.) and for different purposes (e.g., parcel, baggage, component, and part inspection, etc.).

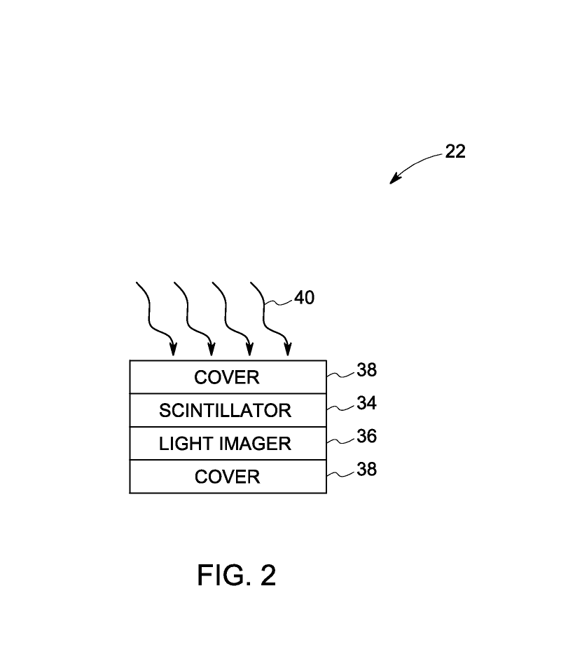

FIG. 2 illustrates a cross-sectional schematic view of an exemplary embodiment of the digital CMOS X-ray detector 22 that includes a scintillator 34 disposed directly on a light imager 36 (e.g., a CMOS light imager). Directly depositing the scintillator 34 on the light imager 36 may improve the detective quantum efficiency (DQE) of the detector. The components of the detector 22 illustrated may represent only some of the components present in such detection systems. For example, these detectors 22 may include electronics and an outer cover 38 and 48. As discussed herein, the digital X-ray detector 22 includes a detector array 42 that includes the scintillator 34 and the light imager 36 (e.g., a CMOS light imager). In addition, the CMOS light imager 36 includes a photosensitive area or pixel array. The scintillator may be fabricated from suitable scintillator compositions such as Cesium Iodide (CsI).

The light imager 36 includes a first surface 44 (e.g., the top surface) and a second surface 46 (e.g., the bottom surface) opposite from the first surface 44. The scintillator 34 is directly disposed on the first surface 44 of the light imager 36.

The scintillator 34 converts X-ray photons 40 to light photons. The light imager 36 converts the light photons to electric signals for acquiring and processing image data. Generally, X-ray photons 40 are emitted from an X-ray radiation source 12, traverse the area in which an object or subject 18 is positioned, and collide with the scintillator 34 within the digital X-ray detector 22. The scintillator 34 absorbs the X-ray photons 40 and emits lower energy light photons that are proportional to the energy and amount of X-ray photons absorbed. As such, light emissions will be higher in those regions of the scintillator 34 where more X-ray photons were received. Since the composition of the object or subject 18 will attenuate the X-ray photons projected by the X-ray radiation source 12 to varying degrees, the energy level and amount of X-ray photons 40 colliding with the scintillator 34 will not be uniform across the scintillator 34. This non-uniformity results in a variation of light emission that will be used to generate contrast in a reconstructed image of the object or subject being imaged.

After the X-ray photons 40 are converted to light photons by the scintillator 34, the resulting light photons emitted by the scintillator 34 are detected by a photosensitive area in the CMOS light imager 36. The photosensitive area may include an array of photosensing elements or pixels to store an electric charge in proportion to the quantity of incident light absorbed by the respective photosensing elements. Generally, each photosensing element has a light sensing region and an electronically-controlled region for the storage and output of electric charge from that photosensing element. The light sensing region may be composed of a photodiode, which absorbs light and subsequently creates and stores an electric charge. After an X-ray exposure, the electric charge in each photodiode is read out and processed by the digital X-ray imaging system 10.

To protect the detector array 42 from light contamination and to provide structural support, an outer cover 38, 48 may be placed around the scintillator 34 and CMOS light imager 36 as shown in FIG. 2. In an exemplary embodiment, the outer cover may include two separate pieces, a first cover 38 and a second cover 48 in a sandwich configuration for enclosing the scintillator 34 and CMOS light imager 36 therebetween. The first cover 38 may be positioned on a top surface of the scintillator 34 and the second cover 48 may be positioned on a bottom surface of the light imager 36. In an exemplary embodiment, the first cover 38 and the second cover 48 may be a single piece that encloses the scintillator 34 and CMOS light imager 36 therein. In certain embodiments, he first and second covers 38, 48 may be fabricated from carbon fiber, metal, metal alloy, plastic, a composite material or other suitable material.

In certain embodiments, light photons emitted from the scintillator 34 may travel towards the first cover 38 instead of the CMOS light imager 36. To redirect the light photons, the detector array 42 may include a light reflector, comprised of silver or other suitable light reflective material, disposed on a surface (e.g., a top surface) of the scintillator 34 opposite the light imager 36. The light reflector is designed to reflect light photons from the scintillator 34 back towards the CMOS light imager 36 resulting in less quantum noise, a stronger light signal, and more efficient overall performance of the digital X-ray detector 22.

In order to block moisture contamination, the digital X-ray detector 22 may include a moisture blocking layer and a sealing material. In certain embodiments, the moisture blocking layer or moisture blocking material (e.g., aluminum film) may be disposed between the outer cover 38, 48 and the detector array 42. In particular, a first moisture blocking layer may be disposed between the first cover 38 and the scintillator 34 or light reflector, and a second moisture blocking layer may be disposed between the light imager 36 and the second cover 48. In certain embodiments, a suitable waterproof sealing material may be disposed around the outer edges of the detector array 42 to seal the components of the detector array 42, including the scintillator 34, light imager 36, and a light reflector disposed on a surface (e.g., a top surface) of the scintillator 34.

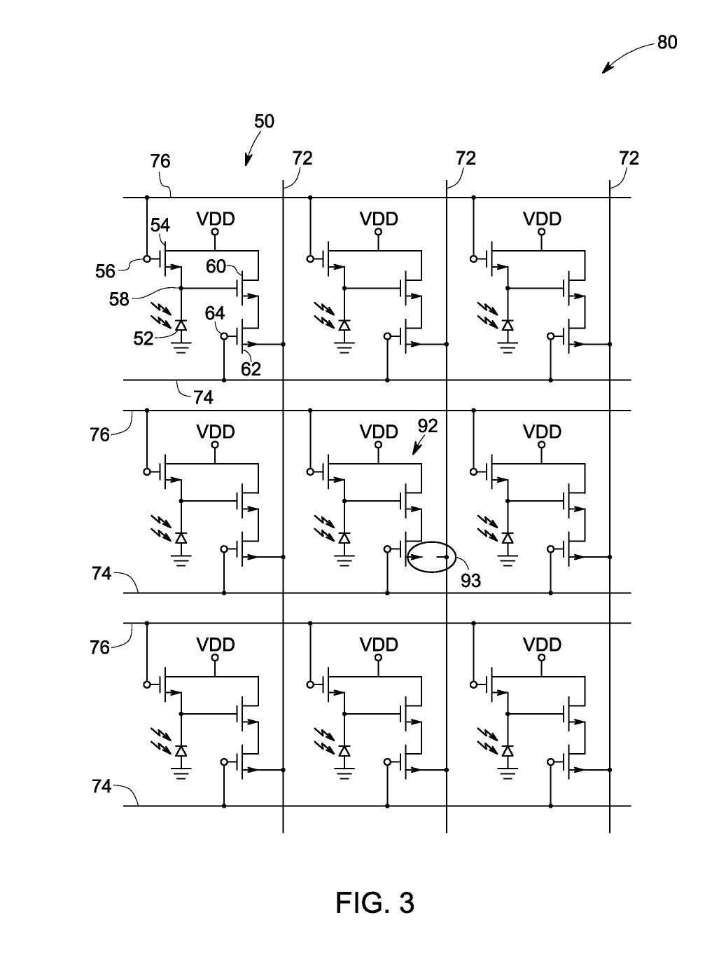

FIG. 3 illustrates a schematic diagram of an exemplary embodiment of a repaired CMOS pixel array 80 within a digital CMOS X-ray detector with a defective CMOS pixel 92 isolated from a common column data line 72. The repaired CMOS pixel array 80 includes an array of individual CMOS pixels 50 in an x-y grid allowing the pixels to be accessed individually. The accessibility of the individual CMOS pixels 50 in the repaired CMOS pixel array 80 is achieved via a row select scan line 74 and a common column data line 72. The row select scan line 74 is used to address one row at a time while the common column data line 72 is used to address one column at a time. The common column data line 72 sequentially addresses all of the columns during the period when their row is being addressed by the row select scan line 74. The common column data line 72 connects the output of all the CMOS pixels 50 in the same column of the repaired CMOS pixel array 80 through the row select gate 64. The row select gate 64 disconnects all CMOS pixels except the selected CMOS pixel. The row select scan line 74 is used to select the desired row of CMOS pixels to be read out. Similarly, the reset line 76 is used to reset all of the CMOS pixels in a row.

Each CMOS pixel 50 includes a photodiode 52, a reset gate 56 on a reset transistor 54, a charge amplifier gate 58 on an charge amplifier transistor 60, and a row select gate 64 on a row select transistor 62. Each CMOS pixel 50 is accessed by a common column data line 72, a row select scan line 74, and a reset line 76.

The cathode of the photodiode 52 is electrically coupled to the charge amplifier node 58, which is electrically coupled to the source of the reset transistor 54 and the gate of the charge amplifier transistor 60. The anode of the photodiode 52 is electrically coupled to ground. The drains of the reset transistor 54 and the charge amplifier transistor 60 are electrically coupled to a supply voltage VDD. The source of the charge amplifier transistor 60 is electrically coupled to the drain of the row select transistor 62. The source of the row select transistor 62 is electrically coupled to the common column data line 72. The reset gate 56 is electrically coupled to the reset line 76. The row select gate 64 is electrically coupled to the row select scan line 74.

In certain embodiments, a CMOS pixel may include three or four transistors, depending on the pixel structure. A three transistor CMOS pixel configuration includes a photodiode, a charge amplifier transistor, a reset transistor, and a row select transistor. Operation of a three transistor CMOS pixel includes X-ray photons being converted into light photons by a scintillator and the light photons being converted into electrons by the photodiode and accumulated as electrical charge. The electrical charge is amplified by the charge amplifier transistor and fed onto a common column data line to be read out through the row select transistor. The purpose of the reset transistor is to clear the electrical charge after it is read out.

A four transistor CMOS pixel configuration includes a photodiode, a transfer gate coupled between the photodiode and a floating diffusion node, a charge amplifier transistor, a reset transistor, and a row select transistor. Compared to the three transistor configuration, the four transistor configuration has less electronic noise and better linearity. The lower electronic noise is achieved in the four transistor configuration by implementing correlated double sampling. Because of variation of the supply voltage VDD, photodiodes may be set to different potentials after reset, which introduces noise known as reset noise. Reset noise is one of the major contributors of the electronic noise in digital CMOS X-ray detectors. In the four transistor CMOS pixel configuration, reset noise may be eliminated by turning on the transfer gate during reset so that the reset noise is transferred and stored in the floating diffusion node. After reset, the transfer gate is turned off and the floating diffusion node is insulated from the photodiode. When the image data is read out, the reset noise stored in the floating diffusion is sampled first. The signal in the photodiode is transferred to the floating diffusion node and is sampled second. The reset noise is then subtracted from the signal. The pixel readout process contains two correlated samplings hence is called correlated double sampling.

During manufacturing of the CMOS light imager, there may be defects in a CMOS pixel array due to, for instance, dust particles or other particles in the cleanroom of the CMOS fabrication facility creating shorts among individual CMOS pixels in a CMOS pixel array. For example, if the row select gate of a CMOS pixel is shorted by a dust particle or other particle, the CMOS pixel with the shorted row select gate will always be connected to the common column data line 72 no matter if the CMOS pixel is selected by the row select scan line or not, which results in a defective common column data line that creates image artifacts in the resulting images. The occurrence of defective CMOS pixels within a CMOS pixel array is eliminated by repairing the CMOS pixel array by isolating the defective CMOS pixels from the CMOS pixel array. A defective CMOS pixel may be isolated from the CMOS pixel array by cutting traces between the defective CMOS pixel and the common column data line, row select scan line, or reset line. This is critical to improving the manufacturing yield of digital CMOS X-ray detectors. Often, a detector panel must be scraped if too many of the CMOS pixels are defective, or a limited number of defective lines.

Referring to FIG. 3, the defective CMOS pixel 92 may be isolated from the CMOS pixels 50 on the same column of the CMOS pixel array 80 by cutting a trace 93 between the source of the row select transistor 62 and the common column data line 72. The CMOS pixel array 80 may be repaired by isolating the defective CMOS pixel 92 from the common column data line 72 by cutting the trace 93 between the source of the row select transistor 62 and the common column data line 72 by a laser cutting apparatus or other cutting means, such as a mechanical cutting apparatus.

In certain embodiments, identifying the column and row location of a defective CMOS pixel within a CMOS pixel array is accomplished by reading the CMOS light imager after an exposure of constant intensity light photons. The CMOS pixel array of the CMOS light imager is read in either a top to bottom array order or a bottom to top array order. In the case of a shorted row select gate of a defective CMOS pixel, the read signal of the defective pixel is added to all other pixels on the same column during a read. The signal of the defective CMOS pixel will be cleared through reset right after its row is read, thus the contribution of the defective pixel to its next neighboring pixel on the same column will be almost zero, which results in a signal drop on the row direction. A relatively strong constant intensity light is recommended to eliminate the effect of noise during testing to determine the location of defective pixels within a CMOS pixel array.

Even though it is very unlike to occur, if there are more than one defective pixel on the same column of the pixel array, their row locations may be identified by the same approach described above. In that case, there would be multiple signal drops instead of a single signal drop described above to identify the row location of a defective pixel within the same column.

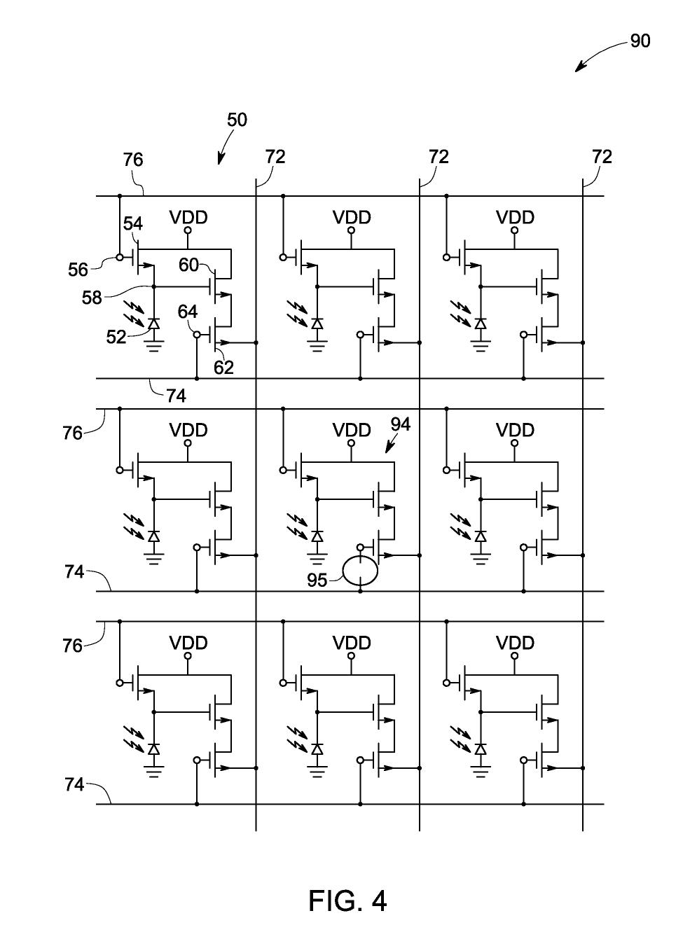

FIG. 4 illustrates a schematic diagram of an exemplary embodiment of a repaired CMOS pixel array 90 within a digital CMOS X-ray detector with a defective CMOS pixel 94 isolated from a row select scan line 74. The defective CMOS pixel 94 may be isolated from the CMOS pixels 50 on the same row of the CMOS pixel array 90 by cutting a trace 95 between the row select gate 64 of the row select transistor 62 and the row select scan line 74. The CMOS pixel array 90 may be repaired by isolating the defective CMOS pixel 94 from the row select scan line 74 by cutting the trace 95 between the row select gate 64 of the row select transistor 62 and the row select scan line 74 by a laser cutting apparatus or other cutting means, such as a mechanical cutting apparatus.

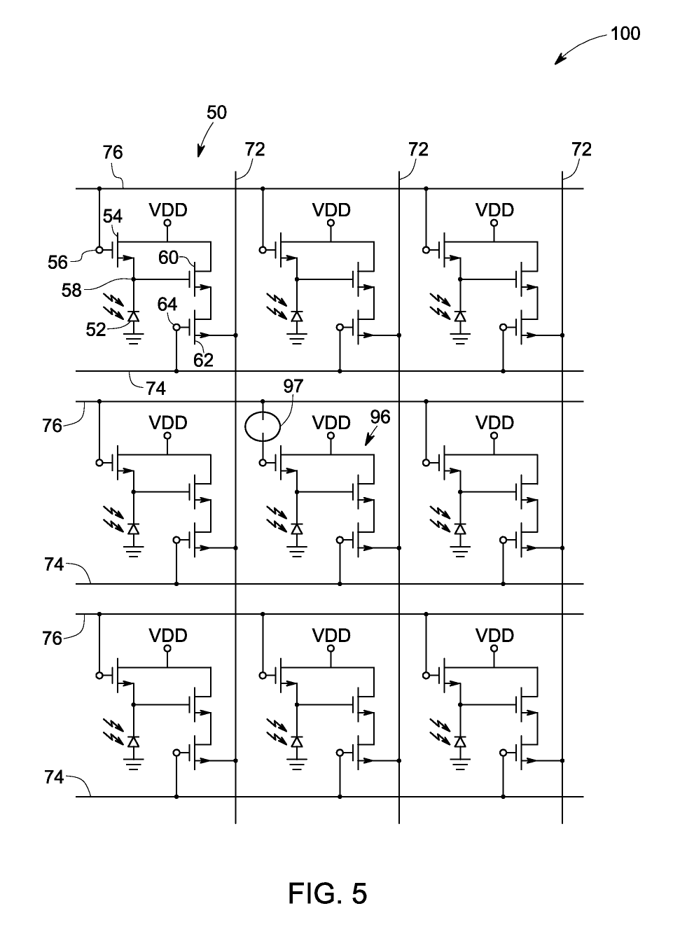

FIG. 5 is a schematic diagram of an exemplary embodiment of a repaired CMOS pixel array 100 within a digital CMOS X-ray detector with a defective CMOS pixel 96 isolated from a reset line 76. The defective CMOS pixel 96 may be isolated from the CMOS pixels 50 on the same row of the CMOS pixel array 100 by cutting a trace 97 between the reset gate 56 of the reset transistor 54 and the reset line 76. The CMOS pixel array 100 may be repaired by isolating the defective CMOS pixel 96 from the reset line 76 by cutting the trace 97 between the reset gate 56 of the reset transistor 54 and the reset line 76 by a laser cutting apparatus or other cutting means, such as a mechanical cutting apparatus.

In accordance with a method of repairing a CMOS pixel array, the column and row locations of defective CMOS pixels within the CMOS pixel array are identified. Next, the defective CMOS pixels are isolated from the from the CMOS pixel array by cutting at least one trace between the defective CMOS pixel and a common column data line, a row select scan line, or a reset line.

The technical advantage of the subject matter of this disclosure is that it isolates defective CMOS pixels within a CMOS pixel array, thereby, greatly reducing the number of defective lines in CMOS detector arrays, improving the manufacturing yield of CMOS detector arrays, and reducing the cost of CMOS detector arrays. This results in improved manufacturing yield and reduced cost of digital CMOS X-ray detectors.

This written description uses examples to disclose the present subject matter, including the best mode, and also to enable any person skilled in the art to practice the present approaches, including making and using any devices or systems and performing any incorporated methods. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A digital X-ray detector comprising:
a scintillator configured to absorb radiation emitted from an X-ray radiation source and to emit light photons in response to the absorbed radiation; and
a complementary metal-oxide-semiconductor (CMOS) light imager configured to absorb the light photons emitted by the scintillator, wherein the CMOS light imager comprises a first surface and a second surface, wherein the first surface is disposed opposite the second surface, and the scintillator contacts the first surface of the CMOS light imager;
wherein the CMOS light imager comprises a repaired CMOS pixel array with at least one defective CMOS pixel isolated from a common column data line, a row select scan line, or a rest line within the CMOS pixel array.

2. The digital X-ray detector of claim 1, wherein the scintillator comprises cesium-iodide (CsI).

3. The digital X-ray detector of claim 1, comprising a first cover positioned on a top surface of the scintillator.

4. The digital X-ray detector of claim 3, comprising a second cover positioned on a bottom surface of the CMOS light imager.

5. The digital X-ray detector of claim 4, wherein one or both of the first or second covers comprises a carbon fiber, metal, metal alloy, plastic, composite material, or a combination thereof.

6. The digital X-ray detector of claim 4, wherein the first and second covers comprise a single piece that encloses the scintillator and CMOS light imager therein.

7. The digital X-ray detector of claim 1, wherein the defective CMOS pixel is isolated from the CMOS pixels on the same column of the CMOS pixel array by cutting a trace between a source of a row select transistor and the common column data line.

8. The digital X-ray detector of claim 7, wherein the trace is cut by a laser cutting apparatus.

9. The digital X-ray detector of claim 7, wherein the trace is cut by a mechanical cutting apparatus.

10. The digital X-ray detector of claim 1, wherein the defective CMOS pixel is isolated from the CMOS pixels on the same row of the CMOS pixel array by cutting a trace between a row select gate of a row select transistor and the row select scan line.

11. The digital X-ray detector of claim 10, wherein the trace is cut by a laser cutting apparatus.

12. The digital X-ray detector of claim 10, wherein the trace is cut by a mechanical cutting apparatus.

13. The digital X-ray detector of claim 1, wherein the defective CMOS pixel is isolated from the CMOS pixels on the same row of the CMOS pixel array by cutting a trace between a reset gate of a reset transistor and the reset line.

14. The digital X-ray detector of claim 13, wherein the trace is cut by a laser cutting apparatus.

15. The digital X-ray detector of claim 13, wherein the trace is cut by a mechanical cutting apparatus.

16. A detector array comprising:
a scintillator configured to absorb radiation emitted from an X-ray radiation source and to emit light photons in response to the absorbed radiation; and
a complementary metal-oxide-semiconductor (CMOS) light imager configured to absorb the light photons emitted by the scintillator, wherein the scintillator contacts the CMOS light imager;
wherein the CMOS light imager comprises a repaired CMOS pixel array with at least one defective CMOS pixel isolated from a common column data line, a row select scan line, or a rest line within the CMOS pixel array.

17. The detector array of claim 16, wherein the defective CMOS pixel is isolated from the CMOS pixels on the same column of the CMOS pixel array by cutting a trace between a source of a row select transistor and the common column data line.

18. The detector array of claim 17, wherein the trace is cut by a laser cutting apparatus.

19. The detector array of claim 17, wherein the trace is cut by a mechanical cutting apparatus.

20. The detector array of claim 16, wherein the defective CMOS pixel is isolated from the CMOS pixels on the same row of the CMOS pixel array by cutting a trace between a row select gate of a row select transistor and the row select scan line.

21. The detector array of claim 20, wherein the trace is cut by a laser cutting apparatus.

22. The detector array of claim 20, wherein the trace is cut by a mechanical cutting apparatus.

23. The detector array of claim 16, wherein the defective CMOS pixel is isolated from the CMOS pixels on the same row of the CMOS pixel array by cutting a trace between a reset gate of a reset transistor and the reset line.

24. The detector array of claim 23, wherein the trace is cut by a laser cutting apparatus.

25. The detector array of claim 23, wherein the trace is cut by a mechanical cutting apparatus.

26. A method for repairing a CMOS pixel array comprising:
identifying defective CMOS pixels within the CMOS pixel array; and
isolating the defective CMOS pixels from the CMOS pixel array by cutting at least one trace between a defective CMOS pixel and a common column data line, a row select scan line, or a reset line.
